(19) United States
(12) Patent Application Publication
(10) Pub. No.: US 2013/0330871 A1
(43) Pub. Date: Dec. 12, 2013

(54) METHODS FOR TEXTURING A SEMICONDUCTOR MATERIAL

(71) Applicants: Bonna Newman, Mountain View, CA (US); Venkatesan Murali, San Jose, CA (US); Zhiyong Li, Los Altos, CA (US); Liang Chen, Fremont, CA (US)

(72) Inventors: Bonna Newman, Mountain View, CA (US); Venkatesan Murali, San Jose, CA (US); Zhiyong Li, Los Altos, CA (US); Liang Chen, Fremont, CA (US)

(73) Assignee: TWIN CREEKS TECHNOLOGIES, INC., San Jose, CA (US)

(21) Appl. No.: 13/494,687

(22) Filed: Jun. 12, 2012

(51) Int. Cl. H01L 31/18

(52) U.S. Cl. 438/71; 257/E31.13

(57) ABSTRACT

A method for modifying the texture of a semiconductor material is provided. The method includes performing a first texture step comprising reactive ion etching to a first surface of semiconductor material. After the first texture step, the first surface of the semiconductor material has a random texture comprising a plurality of peaks and a plurality of valleys, and wherein at least fifty percent of the first surface has a peak-to-valley height of less than one micron and an average peak-to-peak distance of less than one micron. Additional texture steps comprising wet etch or RIE etching may be optionally applied.

### BACKGROUND OF THE INVENTION

A conventional photovoltaic cell includes a p-n diode, where a depletion zone forms at the p-n junction. Light enters the photovoltaic cell and generates current. If any light passes entirely through the cell and escapes without being absorbed, cell efficiency is reduced. Thus, methods are employed to increase travel distance of light within a photovoltaic cell, including reducing reflection at the front surface of the cell, reflecting light from the back surface of the cell, and bending light at either the front or back surface. One method to increase travel length of light in a photovoltaic cell is to create texture at the front and/or back surface.

Reactive-ion etching (RIE) is a dry etching technology used in microfabrication that involves applying a plasma stream to a multicrystalline wafer to form features on the surface of a wafer. Conventionally-used RIE etching techniques result in deep, sharp features which are so deep that they would be detrimental to the surface of a thin lamina. The multicrystalline wafers generally provided for use with these methods are thick and possess a degree of coarseness that is not corrected by conventional RIE methods. In conventional monocrystalline silicon photovoltaic cells, RIE methods may be used to remove damage from a surface, also at the expense of a great deal of silicon. Texturing the surface of monocrystalline material is conventionally achieved using wet crystallographic etch methods. One commonly used etch method produces a pyramid shaped texture, with average peak-to-valley distances on the order of ten microns. Such surface texturing is effective for a wafer which is, for example, 200-400 microns thick or more.

### SUMMARY OF THE INVENTION

A method for modifying the texture of a semiconductor material is provided. The method includes performing a first texture step comprising reactive ion etching to a first surface of semiconductor material. After the first texture step, the first surface of the semiconductor material has a random texture comprising a plurality of peaks and a plurality of valleys, and wherein at least fifty percent of the first surface has a peak-to-valley height less than one micron and an average peak-to-peak distance of less than one micron. Additional texture steps comprising RIE or wet etching methods may be optionally applied.

### BRIEF DESCRIPTION OF THE DRAWINGS

Each of the aspects and embodiments of the invention described herein can be used alone or in combination with one another. The aspects and embodiments will now be described with reference to the attached drawings.

FIGS. 1a and 1b are cross-sectional views showing stages in the formation of the photovoltaic device of Sivaram et al., U.S. patent application Ser. No. 12/026,530 and Kell et al., U.S. patent application Ser. No. 13/331,909.

FIGS. 2a and 2b are cross-sectional views illustrating texturing on the front or back surface of a prior art photovoltaic cell to increase the travel length of light within the cell.

FIG. 3 is a flow chart showing steps of an exemplary method according to aspects of the present invention.

FIG. 4 is a flow chart showing steps of an exemplary method according to aspects of the present invention.

FIG. 5 is a schematic diagram of an example of a reactive ion etching process.

FIGS. 6a through 6c are cross-sectional views illustrating lamina texture according to embodiments of the present invention.

FIGS. 7a and 7b show top views of SEM images of textured lamina according to embodiments of the present invention. FIG. 7c is a cross-sectional SEM image according to embodiments of the present invention

FIG. 8 is a graph of reflectance data of textured lamina according to embodiments of the present invention.

FIG. 9 is a cross-sectional view showing a photovoltaic cell comprising textured lamina according to an embodiment of the present invention.

### DETAILED DESCRIPTION

Recently, methods have been developed to fabricate thin lamina from semiconductor wafers on temporary or permanent supports. The present description provides a method for modifying the texture of a surface of a thin lamina using reactive ion etching of a surface of the lamina in a manner that reduces the amount of silicon removed during the process compared to conventional methods, and preserves the integrity of the lamina. In some embodiments, methods are described in which a thin, free standing lamina is contacted to a temporary carrier and textured with reactive ion etch methods. For the purposes of this disclosure, the term “carrier” shall be used interchangeably with “support element” and “susceptor.”

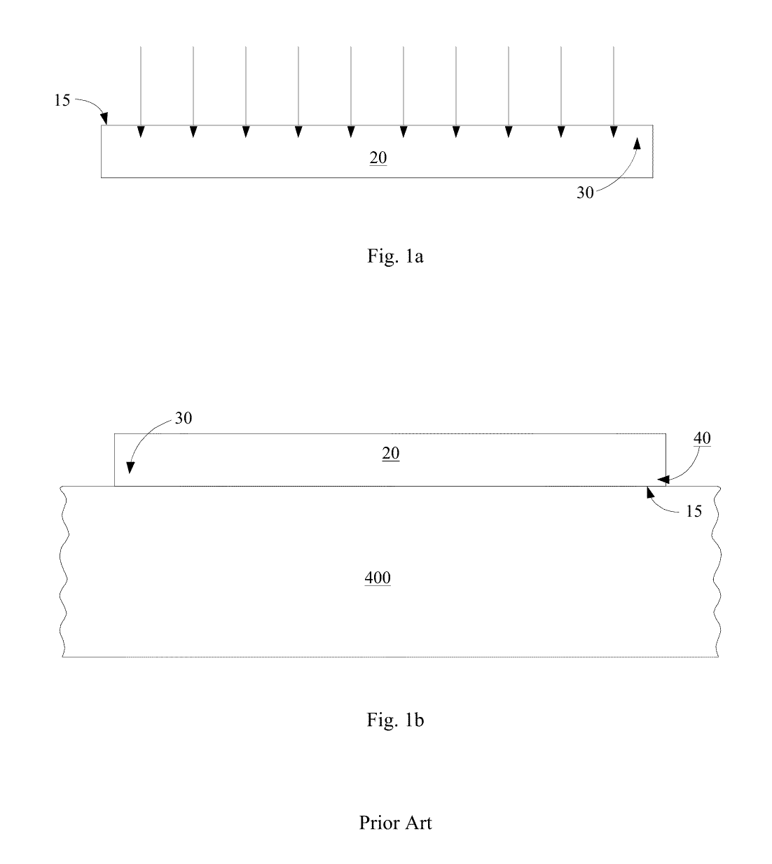

Sivaram et al., U.S. patent application Ser. No. 12/026,530, “Method to Form a Photovoltaic Cell Comprising a Thin Lamina,” filed Feb. 5, 2008, and Kell et al., U.S. patent application Ser. No. 13/331,909, “Method and Apparatus for Forming a Thin Lamina” filed Dec. 20, 2011, both of which are owned by the assignee of the present invention and are hereby incorporated by reference, describe the fabrication of a photovoltaic cell comprising a thin semiconductor lamina formed of non-deposited semiconductor material. Referring to FIG. 1a, a semiconductor donor wafer 20 is implanted through a top surface 15 with one or more species of gas ions, for example hydrogen and/or helium ions. The implanted ions define a cleave plane 30 within the semiconductor donor wafer 20. As shown in FIG. 1b, donor wafer 20 may be contacted at top surface 15 to a support element 400. An anneal step causes a lamina 40 to cleave from donor wafer 20 at cleave plane 30, creating a second surface. In embodiments of Sivaram et al., additional processing before and after the cleaving step forms a photovoltaic cell comprising semiconductor lamina 40, which is between about 0.2 and about 100 microns thick, for example between about 0.2 and about 50 microns, for example between about 1 and about 20 microns thick, in some embodiments between about 1 and about 10 microns thick or between about 4 and about 20 or between about 5 and about 15 microns thick, though any thickness within the named range is possible. Alternatively, a plurality of donor wafers may be affixed to a single, larger receiver, and a lamina cleaved from each donor wafer. In embodiments of Kell et al., shown in FIG. 1b, lamina 40 may be free standing after exfoliation and not bonded to any support element such as support element 400.

In one implementation embodiment, the donor body is separably contacted with a temporary carrier, without adhesive or permanent bonding, where the temporary carrier is a support element such as a susceptor assembly as described in Kell in order to stabilize the lamina during exfoliation. In conventional methods, donor bodies or thin film silicon lamina in various stages of manufacture may be affixed to temporary carriers using adhesive or via chemical bonding. When adhesive is used, additional steps are required to initiate the debonding of the lamina and/or to clean the surface of the lamina and the temporary carrier after detachment. Alternatively, support elements may be dissolved or otherwise removed and rendered unusable for further support steps. Thus, bonded supports require additional manufacturing steps to remove the support element, and the support element is often for single use only. In contrast, the use of a non-bonded temporary support element advantageously decreases cost by reducing manufacturing steps. Additionally, a non-bonded temporary carrier facilitates processing on either side of the semiconductor lamina since the carrier may be easily detached from the lamina. The contact may be direct contact between the donor body and support element, such as by vacuum or electrostatic force, without adherents or bonding steps that require any chemical or physical steps to disrupt the contact beyond merely lifting the donor body or lamina from the susceptor. The susceptor may then be reused as a support element without further processing.

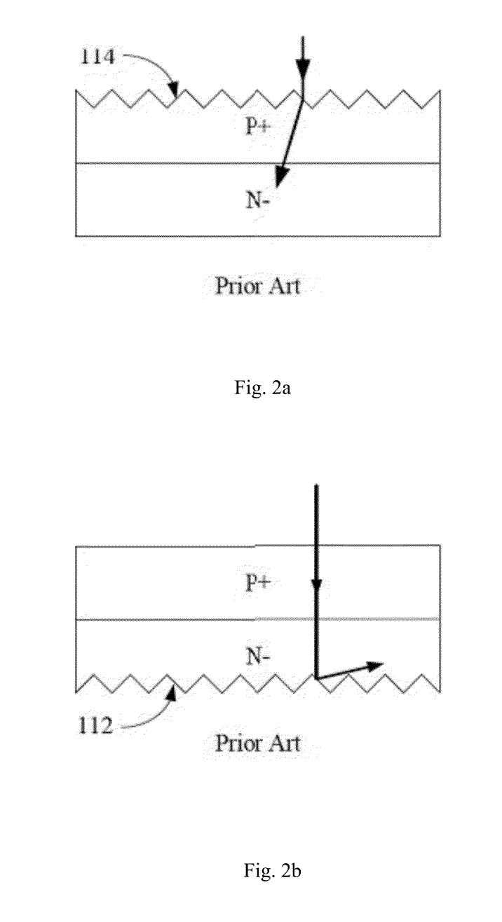

Using the methods of Sivaram et al., and others, photovoltaic cells and other electronic devices, rather than being formed from sliced wafers, are formed of thin semiconductor laminae without wasting silicon through kerf loss or by fabrication of an unnecessarily thick cell, thus reducing cost. The same donor wafer can be reused to form multiple laminae, further reducing cost, and may be resold after exfoliation of multiple laminae for some other use. Thin semiconductor lamina obtained by methods of Sivaram et al., as well as other methods, may be used for in a variety of devices in addition to photovoltaic devices, such as CMOS devices, substrates for 3-D semiconductor packages, LED devices and the like. The texture of the lamina used to fabricate these devices may be modified as shown in FIGS. 2a and 2b in order to improve the optical properties of the devices in a manner that minimizes the amount of semiconductor material lost during the process of the lamina. Some incident light falling on the light-facing surface in a photovoltaic cell or other electronic device will be reflected at that surface, and will never enter the device. Reducing reflectance at the light-facing surface of the semiconductor material thus improves performance. Referring to FIG. 2a, it is well known to texture a light-facing surface 114 of a photovoltaic cell, reducing reflection and causing incident light to be refracted into the cell, as shown. Light may enter the cell, but may pass all the way through the cell without creating any electron-hole pairs, failing to generate any photocurrent and reducing the efficiency of the cell. To avoid allowing light to escape, typically the back surface of the cell is reflective, so that light that passes through the cell is reflected back into the cell from the back surface. Back surface 112 may be textured, as in FIG. 2b, changing the angle of light upon reflection. Either technique serves to increase travel length of light within the cell, improving cell efficiency; often both front and back surfaces are textured. Ideally, surface texturing will reduce reflectance at the light-facing surface and alter the path of light so that all light is internally reflected, and none escapes.

In photovoltaic cells formed from monocrystalline wafers, it is conventional to create surface texture by etching the wafers with a wet etching technique such as the application of a crystallographically selective etchant. Selective etchants (i.e., potassium hydroxide (KOH), sodium hydroxide (NaOH), and tetramethylammonium hydroxide (TMAH)) may etch the <100> and <110> crystallographic planes of silicon at a higher rate than the <111> plane. In a conventional texture step using an etchant such as KOH or TMAH at the surface of a <100> oriented silicon wafer, the surface initially retreats uniformly without forming any texture. After some time, selective etching begins at relatively sparsely distributed points, and pyramids gradually begin to form. After sufficient time, the pyramids meet, and the etch rate slows. About 30 minutes or more of etching at the surface of a standard <100> oriented wafer produces regular pyramids which will typically have a peak-to-valley height on the order of a few microns to tens of microns. Such a surface, as described earlier, decreases reflection from the light-facing surface and increases travel length within the body of the photovoltaic cell.

The surface texture of the present invention may be achieved by using a first texturing step such as reactive ion etching (RIE) to form an appropriate texture on a lamina while reducing the thickness of the lamina by less than 1 micron. The RIE process may be tuned to remove a minimal amount of silicon and create a texture with a small peak-to-valley height that minimizes surface reflectivity while maintaining the integrity of a thin lamina. After the first RIE texturing step, the first surface may have a random texture comprising a plurality of peaks and a plurality of valleys and wherein at least fifty percent of the first surface has a peak-to-valley height less than one micron and an average peak-to-peak distance of less than one micron. The process may be used on any semiconductor material such as a crystallographically oriented monocrystalline wafer in a <111>, <001> or <110> orientation.

The process may be further tuned to create optimal aspect ratios and surface micro-roughness. This includes rounding of sharp features for improved deposition of an electrical contact or passivating material such as a-Si or SiN. The textured surface may be treated with wet etchants (e.g., KOH, NaOH, or TMAH) to clean the newly formed texture and to optionally remove any damage caused by the RIE process. The resulting surface has low reflectance, and in general the relief produced is small, having an average peak-to-valley height of less than about 1 micron, generally less than about 0.8 microns, for example 0.5 microns or less. The peak-to-peak distance may be small as well, such as less than about 1 micron, generally less than about 0.8 microns, for example 0.5 microns or less.

This novel method can be performed either to texture a surface of a conventional silicon wafer having a thickness of 50 microns, 200 microns, or more; or to texture a surface of a thin lamina cleaved from a thicker body such as a silicon wafer, the lamina having a thickness between about 0.5 and about 50 microns, for example between about 0.5 and about 25 microns, or between 5 and 15 microns as described by Sivaram et al., earlier incorporated. The sub-micron relief created by this method is well-suited to the thin lamina produced by the methods of Sivaram et al., or Kell et al. earlier incorporated, because the removal of less than 1 micron during the texturing step or steps insures that the integrity of lamina thinner than 25, 15, or 10 microns is maintained. Clearly it is impractical to use a conventional wet texturing method, which typically consumes ten microns or more of silicon, in order to create surface texture at the surface of a lamina which may have a pre-texturing thickness of 15 microns, 10 microns, 5 microns, or less. RIE methods may also consume 10 microns or more of a wafer thickness and are generally used in connection with a mask to form a deeply etched pattern. Uniform texturing of a thick wafer by RIE methods is challenging because of the amount of silicon loss and the difficulties associated with providing a uniformly flat surface for plasma stream.

Regardless of the thickness of the initial silicon body, the methods of the present invention provide advantages such as a reduced etch time and a more optimum texture shape, particularly for crystallographic orientations that resist wet etching techniques. The methods of this invention provide for improved texturing of certain crystallographic orientations of a monocrystalline material such as a <111> orientation because RIE texturing may be less sensitive to crystallographic orientation. One aspect of the methods of this invention is that the separate texturing of a first and second side of non-bonded lamina without the added steps of debonding and rebonding the lamina is provided for. Another aspect is that thin lamina provided by the methods of Sivaram or Kell allow for a uniform flat surface, ideally suited for the plasma stream in RIE texturing methods of this invention.

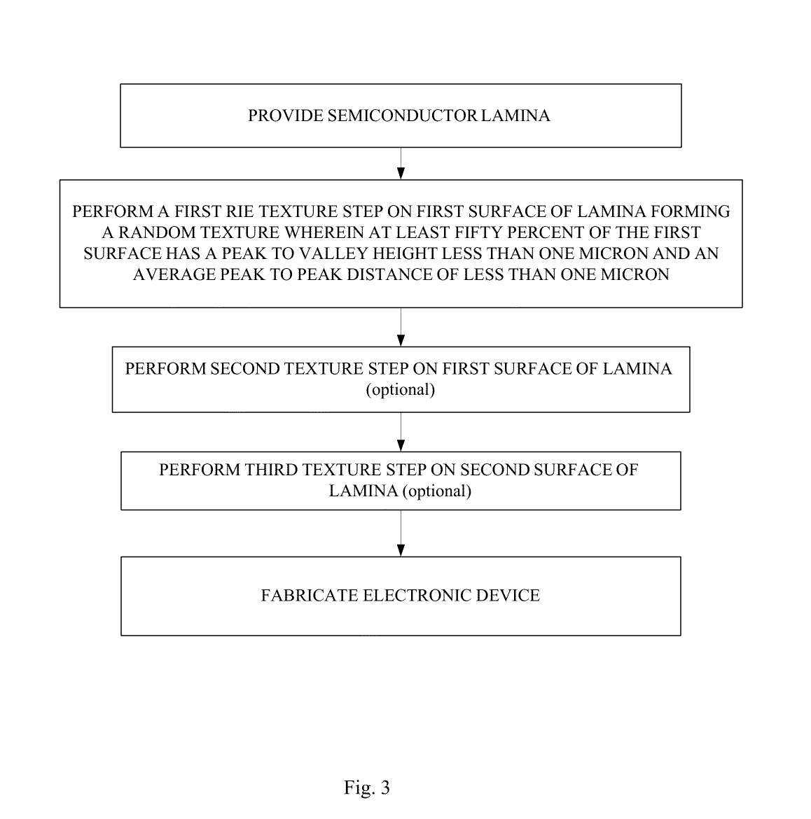

An exemplary method for modifying the surface texture of a semiconductor material for use in an electronic device, such as a light emitting diode (LED) or photovoltaic (PV) cell, is described in the flow chart shown in FIG. 3. In a first step, a semiconductor lamina is provided. The lamina may be a semiconductor material of any thickness. In some embodiments the lamina is a monocrystalline silicon material in any orientation such as <111> orientation. A first texturing step comprising reactive ion etching may occur on a first surface of the lamina forming a random texture on the surface. In some embodiments the RIE etching step may comprise a gas mixture of fluorine (SF₆), chlorine (Cl₂) and (O₂). In some embodiments the power applied to the gas mixture may be between 0.4 and 1.2 Watts/cm². A random texture is formed, for example, without any photolithography or other method to direct the location or pattern of the etching. The texture may comprise pyramid shaped peaks and valleys. In some embodiments, after the etching, at least fifty percent of the first surface has a peak-to-valley height less than one micron and an average peak-to-peak distance of less than one micron. Next, in some embodiments, an optional second texturing step is performed that may round the edges of the peaks and valleys. The second texturing step may comprise a dry etch or a wet etch process.

Dry etching may include any process that comprises bombardment of ions (usually a plasma of reactive gases such as fluorocarbons, oxygen, chlorine, boron trichloride; sometimes with addition of nitrogen, argon, helium and other gases). Wet etching may include any process that comprises an alkaline or acidic solution to affect the texture of the semiconductor material. In some embodiments, the second texture step is an RIE process which results in the rounding of the majority of peaks in the textured surface of the lamina. In some embodiments, the second texturing step may comprise the immersion of the lamina into an alkaline bath. The thin layer of surface damage initiated by the first texturing step by RIE may provide for more uniform distribution of sites to initiate etching in a wet chemical bath, resulting in a more uniformly textured surface. This site initialization function is particularly useful for texturing <111> oriented lamina, or lamina without saw-cut damage while keeping the total silicon loss less than 1 micron. In some embodiments, greater than 75% of the surface may adopt a {111} orientation. An optional third texture step may be performed on the opposite (second) side of the lamina. The texture step on the second side of the lamina may be similar to the texture step on the first side of the lamina. The lamina may then be processed by any means in order to fabricate an electronic device (e.g., PV cell, LED), such as treatment with wet etchants (e.g., KOH, NaOH, TMAH) to remove any RIE damage to the lamina. In some embodiments, a post texturing step may include the application of a passivating layer such as amorphous or intrinsic silicon on the first or second textured surface.

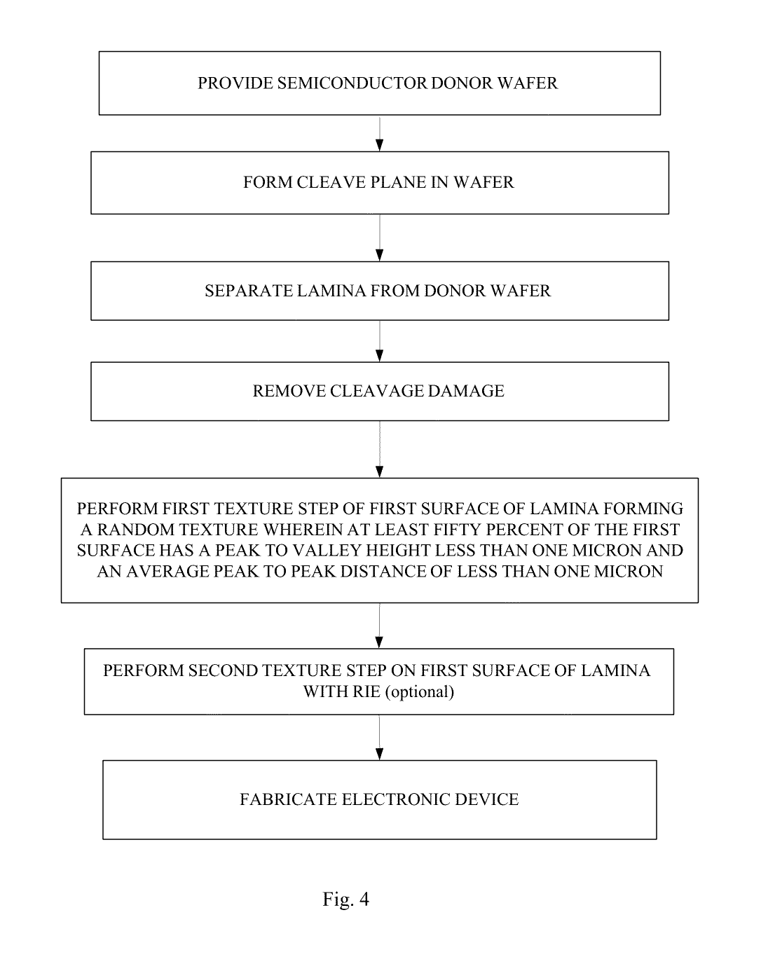

Recall that in embodiments using the methods of Sivaram et al., to create a lamina, a first surface of a silicon donor body is implanted with ions to define a cleave plane, then bonded or adhered to a support element. As outlined in the exemplary method of FIG. 4, a semiconductor donor wafer is provided, a cleave plane is formed in the wafer, and a lamina is separated from the donor body at the cleave plane. The cleaving step creates a first surface of the lamina. In some embodiments, damage from the cleavage step is removed or reduced using an RIE treatment step. The RIE treatment to remove cleavage damage is performed under conditions that do not result in a texture as outlined above. For example, RIE treatment to remove cleavage damage may not comprise chlorine gas. RIE treatment to remove cleavage damage may comprise an applied power such as less than 0.4 W/cm², which is lower than applied powers for an RIE texturing step. After treatment to remove cleavage damage, texture is created at the cleaved surface of the lamina using methods according to the present invention such as a first and optionally a second texturing step comprising the application of RIE. The first texturing RIE step on the cleaved surface of a lamina forms a random texture wherein at least fifty percent of the first surface has a peak-to-valley height less than one micron and an average peak-to-peak distance of less than one micron. The reflectivity of the surface may be reduced by the texture formed on the surface of the lamina. In some embodiments a second texture step is performed on the same surface in order to round out the peaks and valleys generated in the first texturing step, providing for an improved surface for the application of additional layers on the surface such as a passivating layer. The second texturing step may be RIE or a wet chemical treatment. In some embodiments, the first RIE texture step can be used to initialize plenty of sites where the second wet etch texture process can easily start. By combining this first RIE initialization step with the second wet etch step, an uniform texture with total silicon loss less than 1 micron can be achieved on any semiconductor material, such as a crystallographically oriented monocrystalline wafer in a <111>, <001> or <110> orientation, and surface morphology, such as polished and non-polished wafers. In further embodiments a third texture step is performed on the opposite surface of the lamina (the surface opposite the cleaved surface). An electronic device such as a photovoltaic cell or LED may be fabricated, wherein the cleaved, textured surface serves as a light-facing surface in the completed device during normal operation.

To summarize, what has been described is a method to texture a surface of a semiconductor material, the method comprising a first texturing step comprising the application of RIE and optionally a second texturing step. After the first RIE texturing step, at least fifty percent of the first surface has a peak-to-valley height less than about one micron and an average peak-to-peak distance of less than about one micron, and wherein, in the completed electronic device, the average reflectance for light having wavelengths between 375 and 1010 nm at the light-facing surface is no more than about five percent. A semiconductor material produced by these methods may create a photovoltaic cell wherein, in the completed cell, average reflectance for light having wavelengths between 375 and 1010 nm is less than about ten percent or about five percent. The lamina may have a textured first surface or a textured second surface, or both surfaces of lamina may be textured.

Very little silicon is lost during any texture step of this invention. By weight, silicon loss per unit area is generally a total of about 0.3 mg/cm² or less at a textured surface. By thickness, less than 1 micron of silicon or semiconductor material is lost by this process. At least 50 percent, and generally at least 95 percent, of the first surface has peak-to-valley height less than about one micron, for example less than about 0.8 micron, in some instances less than about 0.5 microns; and has average peak-to-peak distance less than about one micron, for example less than about 0.8 micron, in some instances less than about 0.5 micron. A photovoltaic cell may be fabricated (specific fabrication examples will be provided) in which the textured surface is a light-facing surface, or, in some embodiments, a back surface. In the finished device, average reflectance for light having wavelengths between 375 and 1010 nm at a light-facing surface is low, about 6 percent or less, for example about 5 percent or less. In some embodiments, reflectance is about 3.5 percent or less.

For clarity, a detailed example of a photovoltaic assembly including a receiver element and a lamina having thickness between 0.2 and 100 microns, in which low-relief surface texture is created according to embodiments of the present invention will be provided. For completeness, many materials, conditions, and steps will be described. It will be understood, however, that many of these details can be modified, augmented, or omitted while the results fall within the scope of the invention.

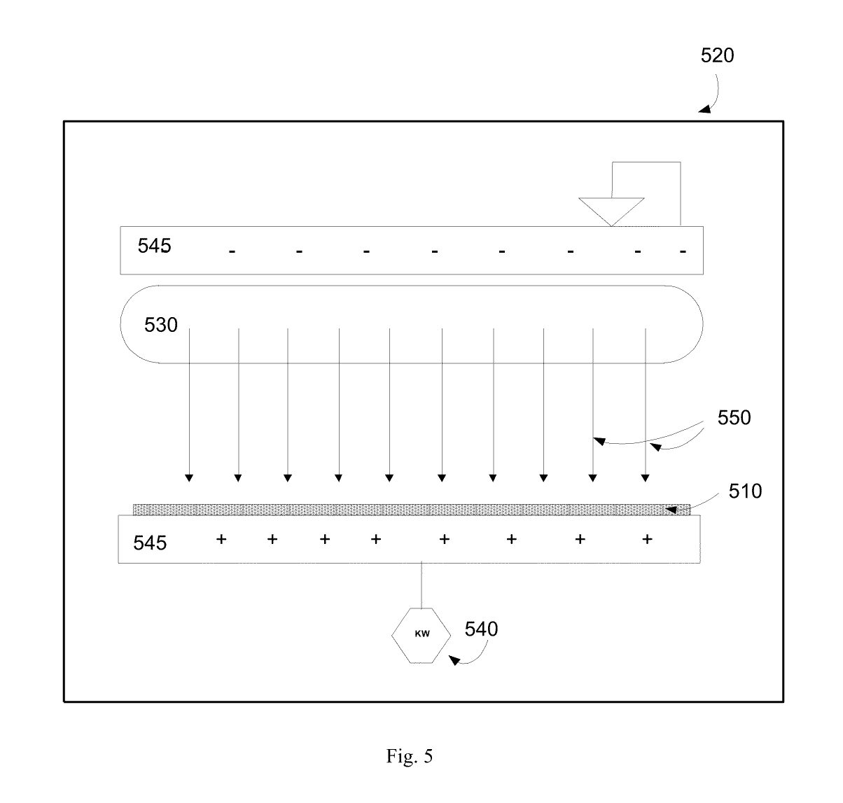

Any number of texture steps such as one, two, or three or more may be utilized in this invention. Any number of the texture steps of this invention may comprise a reactive ion etch process, sometimes referred to as a dry etching technique. During the reactive ion etching process as shown in FIG. 5, a lamina 510 is placed inside a reactor 520 in which several gases 530 are introduced. A plasma is struck in the gas mixture by applying a radio frequency (RF) power from a power source 540 to the gas between electrodes 545, breaking the gas molecules into ions. The ions 550 are accelerated towards the surface of the lamina 510 being etched. Adjusting the balance of gas mixture, power and etching time, gas pressure, and temperature provides for a method to adjust the texture of a lamina while removing a minimum of lamina material. In some embodiments, the gas mixture may comprises SF₆, Cl₂ and O₂ at a ratio of 3.0:1:1.8 standard cubic centimeters per minute. In some embodiments, the flow of gas has a total working pressure between 300 and 500 milliTorr. In some embodiments, the etching time may be between 10 seconds and 7 minutes, such as between 45 seconds and 100 seconds, or between 3.5 minutes and 4.5 minutes. In methods of this invention, the power, gas mixture and etching time are adjusted to form a texture that maximizes the optical properties of the electronic device while minimizing the amount of semiconductor material removed during the process.

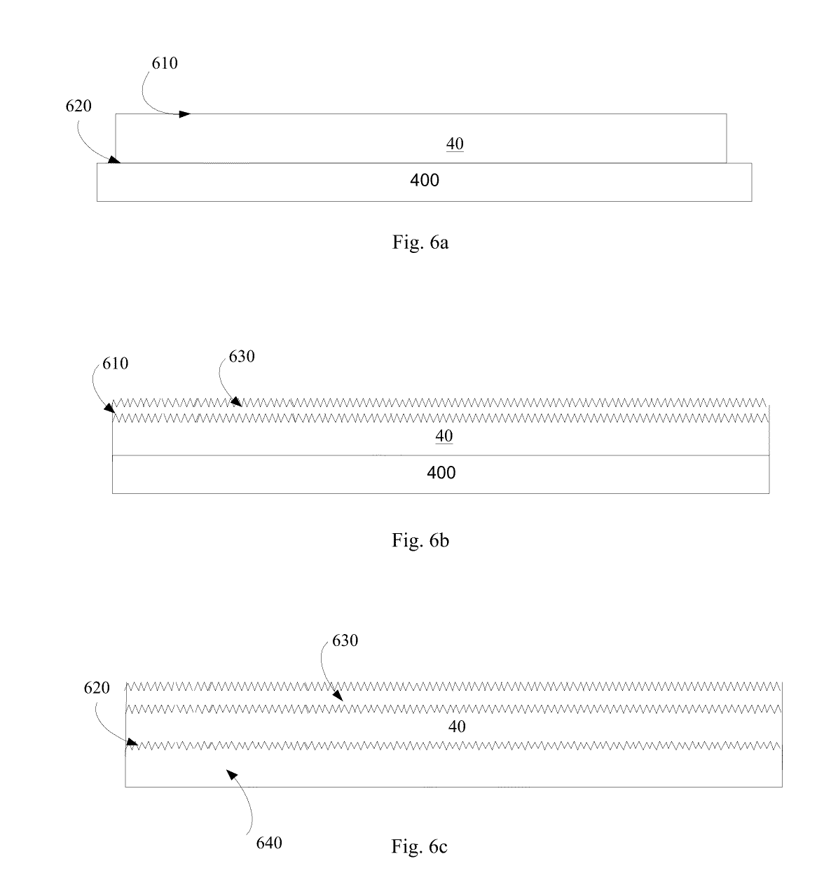

The method may be applied to one or both surfaces of a lamina. In some embodiments as shown in FIG. 6a the method of this invention may be practiced on a free standing lamina 40 that is cleaved and supported by a non bonded support element 400. In some embodiments the first surface 610 of the lamina may be the cleaved surface of the lamina. The second surface 620 may be contacted with support element 400. In some embodiments the lamina may be separably contacted with a support element 400 such as a susceptor assembly wherein the interacting force between the lamina and the support element is solely the weight of the lamina on the support element. Contacting the lamina to a non-bonded support element during the steps of texturing as in some embodiments of the present invention, provides for the convenient texturing of both sides of the lamina without the steps of de-bonding and re-bonding to a support element. FIG. 6b shows lamina 40 having surface 610 textured according to methods of this invention. The textured surface 610 provides for the conformal deposition of a passivating layer 630 such as SiO, amorphous silicon or SiN on the surface. In some embodiments as shown in FIG. 6c, the second surface 620 of lamina 40 may be textured according to methods of this invention. Following the texturing of the second surface 620, a metal receiving layer 640 may be disposed on the surface 620 of lamina 40. The textured second surface of a lamina provides for reduced reflectance, better light trapping, lower series resistance and improved device performance of the lamina in an electronic device.

### Example

The process begins with a donor body of an appropriate semiconductor material. An appropriate donor body may be a monocrystalline silicon wafer of any practical thickness, for example from about 200 to about 1000 microns thick. Typically the wafer has a <100> orientation, though wafers of other orientations may be used. In alternative embodiments, the donor wafer may be thicker; maximum thickness is limited only by practicalities of wafer handling. Alternatively, polycrystalline or multicrystalline silicon may be used, as may microcrystalline silicon, or wafers or ingots of other semiconductor materials, including germanium, silicon germanium, or III-V or II-VI semiconductor compounds such as GaAs, InP, etc. In this context the term multicrystalline typically refers to semiconductor material having grains that are on the order of a millimeter or larger in size, while polycrystalline semiconductor material has smaller grains, on the order of a thousand angstroms. The grains of microcrystalline semiconductor material are very small, for example 100 angstroms or so. Microcrystalline silicon, for example, may be fully crystalline or may include these microcrystals in an amorphous matrix. Multicrystalline or polycrystalline semiconductors are understood to be completely or substantially crystalline. It will be appreciated by those skilled in the art that the term “monocrystalline silicon” as it is customarily used will not exclude silicon with occasional flaws or impurities such as conductivity-enhancing dopants.

The process of forming monocrystalline silicon generally results in circular wafers, but the donor body can have other shapes as well. For photovoltaic applications, cylindrical monocrystalline ingots are often machined to an octagonal cross-section prior to cutting wafers. Wafers may also be other shapes, such as square. Square wafers have the advantage that, unlike circular or hexagonal wafers, they can be aligned edge-to-edge on a photovoltaic module with minimal unused gaps between them. The diameter or width of the wafer may be any standard or custom size. For simplicity this discussion will describe the use of a monocrystalline silicon wafer as the semiconductor donor body, but it will be understood that donor bodies of other types and materials can be used.

In a first step, ions, preferably hydrogen or a combination of hydrogen and helium, are implanted into wafer 20 to define cleave plane 30, as described earlier in FIG. 1b. This implant may be performed using the implanter described in Parrill et al., U.S. patent application Ser. No. 12/122,108, “Ion Implanter for Photovoltaic Cell Fabrication,” filed May 16, 2008; or those of Ryding et al., U.S. patent application Ser. No. 12/494,268, “Ion Implantation Apparatus and a Method for Fluid Cooling,” filed Jun. 30, 2009; or of Purser et al. U.S. patent application Ser. No. 12/621,689, “Method and Apparatus for Modifying a Ribbon-Shaped Ion Beam,” filed Nov. 19, 2009, all owned by the assignee of the present invention and hereby incorporated by reference. The overall depth of cleave plane 30 is determined by several factors, including implant energy. The depth of cleave plane 30 can be between about 0.2 and about 100 microns from first surface 10, for example between about 0.5 and about 20 or about 50 microns, for example between about 1 and about 10 microns or between about 1 or 2 microns and about 5 or 6 microns.

FIG. 1b shows the structure comprising a semiconductor donor wafer 20 inverted with support element 400 on the bottom. The support element 400 may be a temporary or permanent support comprising any material that provides structural support for the lamina such as metal, glass, silicon or any combination thereof. A thermal step causes lamina 40 to cleave from the donor wafer 20 at the cleave plane 30. Cleaving is achieved in this example by exfoliation, which may be achieved at temperatures between, for example, about 350 and about 650 degrees C. In general, exfoliation proceeds more rapidly at higher temperature. The thickness of lamina 40 is determined by the depth of cleave plane 30. In many embodiments, the thickness of lamina 40 is between about 1 and about 25 microns, for example between about 2 and about 15 microns, for example about 10 microns.

Referring to FIG. 6a, a first surface 610 is been created by exfoliation. The lamina in this example is mono crystalline silicon lamina that is 10 microns thick, but any semiconductor material of any thickness may be utilized with the methods of this invention. The lamina was cleaned by dipping the lamina into hydrofluoric acid and implant damage was removed with the application of an RIE damage removal step comprising and O₂:SF₆ gas at a ratio of 1:4 standard cubic centimeters per minute (scc/min) and 300 mTorr with 0.8 W/cm² of power applied for 90 seconds. A thickness of about 0.7 microns of semiconductor material was removed by this step. No texture was formed by this process, merely the removal of damage caused by the cleavage of the lamina from the donor wafer. The reflectance of the lamina was measured at this point and was shown to be greater than 40% at wavelengths between 375 nm to 1050 nm.

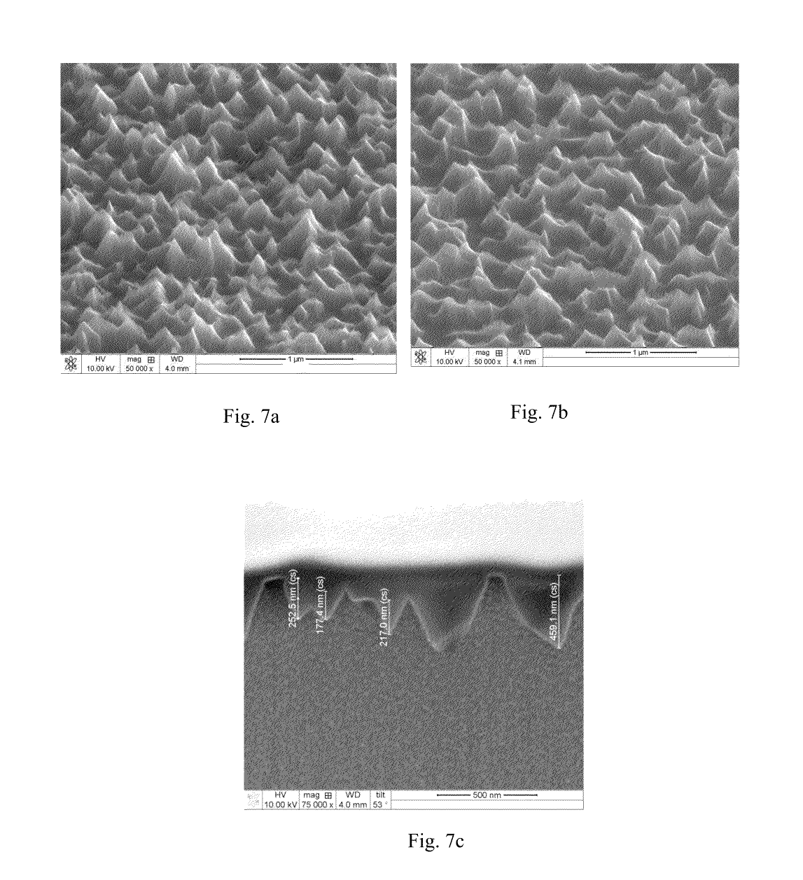

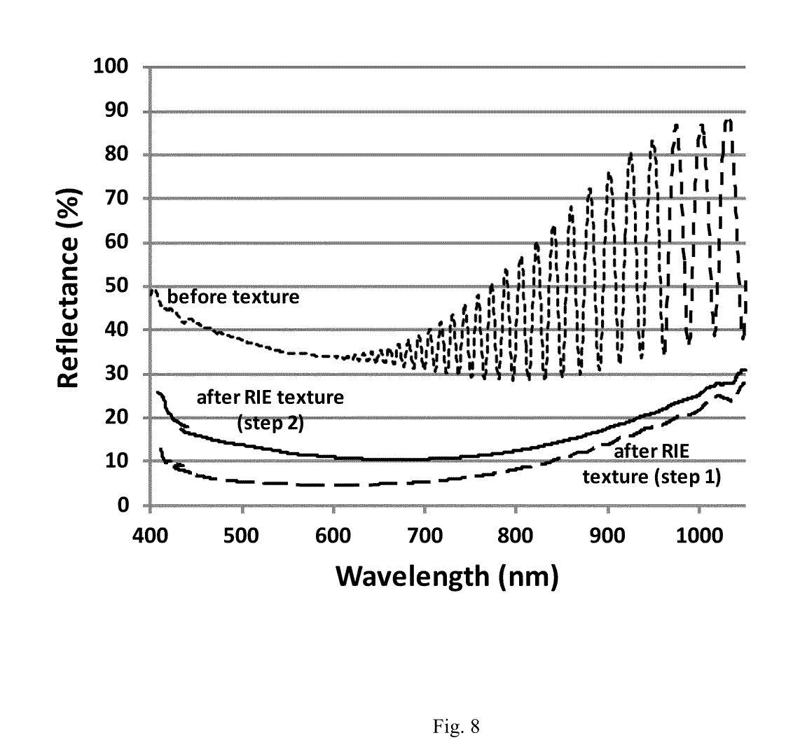

Next, the first surface 610 was textured according to an embodiment of the present invention. A first texturing step was performed on the first side of the lamina with the application of an RIE process using a gas mixture comprising SF₆, Cl₂, and O₂ at a ratio of 2:7:11 scc/min and a pressure of 350 mTorr with 0.8 W/cm² of power applied for 240 seconds. A second RIE texturing step followed the first texturing step on the same side of the lamina, to smooth peaks and valleys generated in the first texturing step. The second RIE texture step comprised the gases SF₆ and Cl₂ at a ratio of 3:1 scc/min and a pressure of 400 m Torr with a power of 0.5 W/cm² applied for 30 sec. After the first and second texturing steps, the lamina was treated with an acidic wet process to remove 10-20 nm of plasma damage left by the RIE process, but without substantially changing the shape of the texture. Scanning electron microscope (SEM) images and reflectance measurements were taken of the lamina before the texturing and after the first and second RIE texture steps. The SEM image shown in FIG. 7a depicts the peaks and valleys of the texture of the lamina after the first RIE texture step. FIG. 7b shows the texture of the lamina after the second RIE texture step where the peaks and valleys are smoothed and rounded. A cross section of an SEM image is shown in FIG. 7c which depicts the lamina after the second RIE texture step and shows that the average peak height is less than 1 micron (in some embodiments the peak height may be less than 0.5 microns). After the first and second texture steps, the lamina comprises <111> facets exposed with rounded peaks and few or no re-entrant angles. Reflectance measurements shown in FIG. 8 indicate that a large decrease in reflectance after the first RIE texture step occurred, followed by a small increase in reflectance after the second RIE texture step. While the reflectance may increase after the second texture step, the round texture provides for the improved conformal deposition of a passivating layer on the lamina.

The parameters of the first and second texture steps may vary. In some embodiments the gas used in the RIE process may comprise chlorine in combination with fluorine, oxygen or any combination thereof. In some embodiments the ratio of gases may be SF₆:Cl₂:O₂ at 3.0:1:1.8 scc/min or 1.0:3.0:6.0 scc/min. In some embodiments the power applied to the gasses may be between 0.84 and 1.2 Watt/cm², or between 0.8 and 1.0 Watt/cm². In some embodiments the flow of gas may last between 10 seconds and 7 minutes, or between 45 seconds and 100 seconds, or between 3.5 minutes and 4.5 minutes.

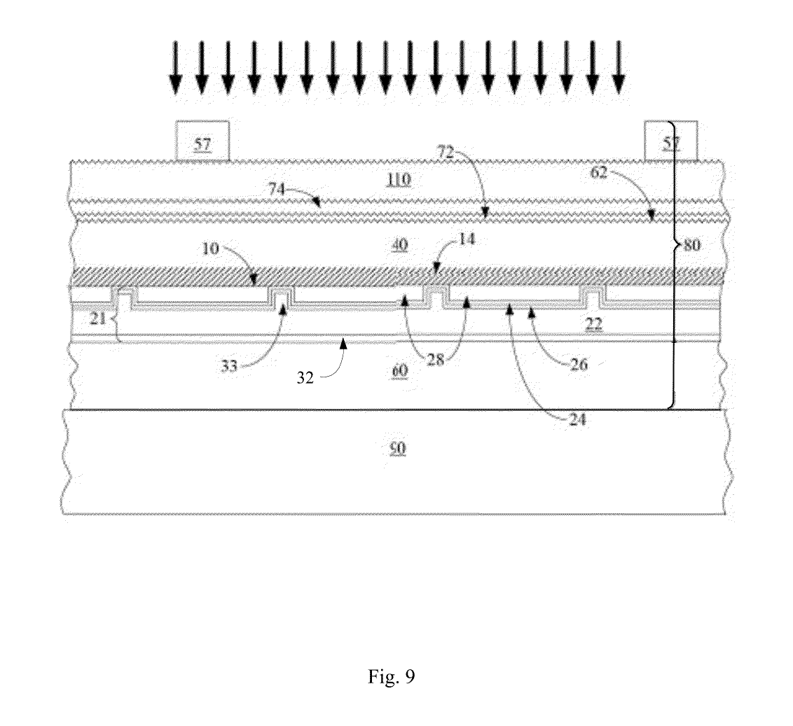

An electronic device may be fabricated from a lamina textured by methods of this invention. The electronic device may be a photovoltaic device comprising a passivating layer on a surface of the lamina. FIG. 9 shows completed photovoltaic assembly 80, which includes a photovoltaic cell and receiver element 60. After cleaning, a silicon layer 74 is deposited on second surface 62 of lamina 40. This layer 74 includes heavily doped silicon, and may be amorphous, microcrystalline, nanocrystalline, or polycrystalline silicon, or a stack including any combination of these. This layer or stack may have a thickness, for example, between about 50 and about 350 angstroms. Some embodiments include an intrinsic amorphous silicon layer 72 between second surface 62 and doped layer 74. In other embodiments, layer 72 may be omitted. In this example, heavily doped silicon layer 74 is doped p-type, opposite the conductivity type of lightly doped n-type lamina 40, and serves as the emitter of the photovoltaic cell being formed, while lightly doped n-type lamina 40 comprises the base region. If included, layer 72 is sufficiently thin that it does not impede electrical connection between lamina 40 and doped silicon layer 74. Note that in general deposited amorphous silicon is conformal; thus the texture at surface 62 is reproduced at the surfaces of silicon layers 72 and 74, providing for improved passivation of the cell.

In alternative embodiments, by changing the dopants used, a heavily doped region 14 may serve as the emitter, at first surface 10, while heavily doped silicon layer 74 serves as a contact to the base region. Incident light (indicated by arrows) falls on transparent conductive oxide (TCO) layer 110, enters the cell at heavily doped p-type amorphous silicon layer 74, enters lamina 40 at second surface 62, and travels through lamina 40. In this embodiment, receiver element 60 serves as a substrate. If receiver element 60 has, for example, a widest dimension about the same as that of lamina 40, the receiver element 60 and lamina 40, and associated layers, form a photovoltaic assembly 80. Multiple photovoltaic assemblies 80 can be formed and affixed to a supporting substrate 90 or, alternatively, a supporting superstrate (not shown). Additional fabrication details of such a cell are provided in Herner, U.S. patent application Ser. No. 12/540,463, “Intermetal Stack for Use in a Photovoltaic Device,” filed Aug. 13, 2009, owned by the assignee of the present application and hereby incorporated by reference.

Openings 33 are formed in dielectric layer 28 by any appropriate method, for example by laser scribing or screen printing. The size of openings 33 may be as desired, and will vary with dopant concentration, metal used for contacts, etc. In one embodiment, these openings may be about 40 microns square. A cobalt or titanium layer 24 is formed on dielectric layer 28 by any suitable method, for example by sputtering or thermal evaporation. This layer may have any desired thickness, for example between about 100 and about 400 angstroms, in some embodiments about 200 angstroms thick or less, for example about 100 angstroms. Layer 24 may be cobalt or titanium or an alloy thereof, for example, an alloy which is at least 90 atomic percent cobalt or titanium. Cobalt layer 24 is in immediate contact with first surface 10 of donor wafer 20 in vias 33; elsewhere it contacts dielectric layer 28. In alternative embodiments, dielectric layer 28 is omitted, and titanium layer 24 is formed in immediate contact with donor wafer 20 at all points of first surface 10. Non-reactive barrier layer 26 is formed on and in immediate contact with cobalt layer 24. This layer is formed by any suitable method, for example by sputtering or thermal evaporation. Non-reactive barrier layer 26 may be any material, or stack of materials, that will not react with silicon, is conductive, and will provide an effective barrier to the low-resistance layer to be formed in a later step. Suitable materials for non-reactive barrier layer include TiN, TiW, W, Ta, TaN, TaSiN, Ni, Mo, Zr, or alloys thereof. The thickness of non-reactive barrier layer 26 may range from, for example, between about 100 and about 3000 angstroms, for example between about 500 and about 1000 angstroms. In some embodiments this layer is about 700 angstroms thick. Low-resistance layer 22 is formed on non-reactive barrier layer 26. This layer may be, for example, cobalt, silver, or tungsten or alloys thereof. In this example low-resistance layer 22 is cobalt or an alloy that is at least 90 atomic percent cobalt and formed by any suitable method. Cobalt layer 22 may be between about 5000 and about 20,000 angstroms thick, for example about 10,000 angstroms (1 micron) thick.

In this example an adhesion layer 32 may be formed on low-resistance layer 22. Adhesion layer 32 is a material that will adhere to receiver element 60, for example titanium or an alloy of titanium, for example an alloy which is at least 90 atomic percent titanium. In alternative embodiments, adhesion layer 32 can be a suitable dielectric material, such as Kapton or some other polyimide. In some embodiments, adhesion layer 32 is between about 100 and about 2000 angstroms, for example about 400 angstroms. Cobalt layer 24, nonreactive barrier layer 26, low-resistance layer 22, and adhesion layer 32 make up intermetal stack 21. In the completed photovoltaic cell, in which light-facing surface 62 was textured according to embodiments of the present invention, average reflectance for light having wavelengths between 375 and 1010 nm at light-facing surface 62 will be no more than about six percent, generally no more than about five percent, for example about 3.5 percent.

A variety of embodiments has been provided for clarity and completeness. Clearly it is impractical to list all possible embodiments. Other embodiments of the invention will be apparent to one of ordinary skill in the art when informed by the present specification. Detailed methods of fabrication have been described herein, but any other methods that form the same structures can be used while the results fall within the scope of the invention. The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed:

1. A method for modifying the texture of semiconductor material, the method comprising:
a. providing a semiconductor lamina having a thickness between a first surface and a second surface;
b. performing a first texture step comprising reactive ion etching to the first surface of the lamina, wherein after the first texture step, the first surface has a random texture comprising a plurality of peaks and a plurality of valleys, and wherein at least fifty percent of the first surface has a peak-to-valley height of less than one micron and an average peak-to-peak distance of less than one micron; and
c. fabricating an electronic device, wherein the electronic device comprises the lamina.

2. The method of claim 1 wherein the electronic device is a photovoltaic cell having a base, and wherein the base comprises the lamina.

3. The method of claim 1 wherein the step of providing the semiconductor lamina comprises:
a) providing a donor body comprising a top surface;
b) implanting ions into the top surface of the donor body to define a cleave plane;
c) exfoliating the lamina from the donor body at the cleave plane, wherein the step of exfoliating the lamina forms the first surface of the lamina, wherein the first surface is opposite the top surface of the donor body, and wherein the top surface of the donor body becomes the second surface of the lamina.

4. The method of claim 1 wherein the reactive ion etching comprises generating a plasma by applying a power to a flow of gas, wherein the gas comprises chlorine, oxygen, fluorine, or any combination thereof.

5. The method of claim 4 wherein the flow of gas comprises chlorine.

6. The method of claim 4 wherein the flow of gas comprises SF₆, Cl₂ and O₂ at a ratio of 3.0:1:1.8 standard cubic centimeters per minute.

7. The method of claim 4 wherein the flow of gas comprises SF₆, Cl₂ and O₂ at a ratio of 1.0:3.0:6.0 standard cubic centimeters per minute.

8. The method of claim 4 wherein the power is between 0.4 and 1.2 Watts/cm².

9. The method of claim 4 wherein the flow of gas has a total working pressure between 300 and 500 milliTorr.

10. The method of claim 1 wherein the lamina is comprised of monocrystalline silicon in a <111> crystal orientation.

11. The method of claim 1 wherein the thickness is less than 25 microns.

12. The method of claim 10 wherein after the first texture step, greater than 50% of the first surface of the lamina is in the {111} crystal orientation.

13. The method of claim 1 wherein the first texture step reduces the thickness of the lamina by less than 1 micron.

14. The method of claim 1, further comprising the step of performing a second texture step to the first surface of the lamina, wherein the second texture step rounds the corners of the peaks and valleys while removing less than 1 micron of the thickness of the lamina.

15. The method of claim 14 wherein the second texture step comprises wet etching, plasma etching, or any combination thereof.

16. The method of claim 14 wherein the second texture step comprises immersing the lamina in an alkaline bath.

17. The method of claim 14, further comprising the step of performing a third texture step to the second surface of the lamina, wherein after the third texture step, the second surface has a random texture comprising a new plurality of peaks and a plurality of valleys, and wherein at least fifty percent of the second surface has a new peak-to-valley height of less than one micron and an average new peak-to-peak distance of less than one micron.

18. The method of claim 17 wherein the third texture step comprises reactive ion etching.
